(19) United States
(12) Patent Application Publication
(10) Pub. No.: US 2007/0001189 A1
(43) Pub. Date: Jan. 4, 2007

(54) Method of fabricating substrate for package of semiconductor light-emitting device

(76) Inventor: Wan-Shun Chou, Taipei County (TW)

Correspondence Address: IPFortune LLC/Ruay Lian Ho, Suite 400, 1700 Pennsylvania Ave., NW, Washington, DC, 20006, US

(21) Appl. No.: 11/287,404

(22) Filed: Nov. 28, 2005

(30) Foreign Application Priority Data
Jul. 1, 2005 (TW) 094211176

(51) Int. Cl. H01L 33/00; H01L 21/50

(52) U.S. Cl. 257/99; 438/22; 257/735; 438/411; 257/676; 438/123; 257/692

(57) ABSTRACT

In the invention, a substrate and fabrication thereof for a package of at least one semiconductor device, such as semiconductor light-emitting devices, are disclosed. In particular, a base together with a frame supporting the base of the substrate according to the invention is formed of a thick-walled metal material, a special-shaped metal plate or a normal-shaped metal plate. The at least one semiconductor device is to mounted on a top surface of the base. Moreover, the base serves as a heat sink.

### BACKGROUND OF THE INVENTION

1. Field of the Invention

The invention relates to a method of fabricating substrate, and more particularly, to a method of fabricating substrate for package of semiconductor device.

2. Description of the Prior Art

Semiconductor chip, e.g. semiconductor light-emitting devices, has been utilized everywhere in our daily life. The advantages of using these semiconductor products, such as small volume and power-saving, facilitate the development of them. However, many of these semiconductor products have the same problem of the rise of temperature which can lead to low efficiency of the operation of the semiconductor chip, even short life-span of the semiconductor chip. A semiconductor chip mounting part, which has excellent heat conduction and dissipation capabilities, is important for a substrate for a package of semiconductor chip.

Moreover, heat dissipating devices, e.g. a heat sink, nowadays often formed by metal materials with excellent heat conductivity, such as copper or aluminum materials, and then be mounted to the semiconductor chip or the carrier of the semiconductor chip. The mounting process of the heat dissipating device can lead to extra costs when manufacturing the substrate.

### SUMMARY OF THE INVENTION

Accordingly, the scope of the present invention is to provide a substrate for a package of at least one semiconductor device, which does not need the extra mounting process of the heat dissipating device, and a method of fabricating the substrate. More particularly, the method can reduce the complexity of the process of fabricating the substrate.

The preferred embodiment, according to the invention, provides a method of fabricating a substrate for a package of at least one semiconductor device. First of all, a first metal plate is punched to form a first frame, a base substantially formed at a center of the first frame, and at least one first supporting part which each is formed to connect between the first frame and the base. In addition, the base has a circumference, a bottom surface, and a top surface.

Afterward, a second metal plate is punched to form a second frame which can mate the first frame. N bonding part, which each has a respective bond pad, is formed apart from a center of the second frame. Furthermore, N outer electrodes, which each is utilized to connect between the second frame and one of the bonding parts, are formed. N is a positive integer larger than or equal to 2.

Then, the second frame is aligned with the first frame, and is palletized on the first frame. Accordingly, the bonding parts are disposed around the circumference of the base and spaced from the base.

Finally, an insulating material is molded to substantially pack the base and the bonding parts, so as to expose the top surface and the bottom surface of the base and the bond pads. When the at least one semiconductor device is mounted on the top surface of the base, the electrodes of the at least one semiconductor device are to be wired to the bond pads.

A substrate for a package of at least one semiconductor device according to the invention comprises a base, N bonding parts, N outer electrodes, and an insulating material. N is a positive integer larger than or equal to 2.

The base has a circumference, a bottom surface and a top surface which the at least one semiconductor device is to be mounted on. Furthermore, the N bonding parts, which each is disposed around the circumference of the base, are spaced from the base, and has a respective bond pad which at least one of the electrodes of the at least one semiconductor device is to be wired to. In addition, each of the N outer electrodes protrudes from one of the bonding parts. Moreover, an insulating material is molded to substantially pack the base and the bonding parts, so as to expose the top surface and the bottom surface of the base, and the bond pads.

After the package of the at least one semiconductor device is finished, a heat generated during operation of the at least one semiconductor device is conducted from the top surface to the bottom surface of the base, and then is dissipated at the bottom surface of the base.

The scope of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1A is a top view of a substrate for a package of at least one semiconductor device according to one embodiment of the invention.

FIG. 1B is a side view of the substrate for a package of at least one semiconductor device shown in FIG. 1A.

FIG. 1C is a bottom view of the substrate for a package of at least one semiconductor device shown in FIG. 1A.

FIG. 2 shows a top view of a substrate for a package of at least one semiconductor device according to one embodiment of the invention.

FIG. 3A through FIG. 3D illustrate a method of fabricating a substrate for a package of at least one semiconductor device according to one embodiment of the invention.

### DETAILED DESCRIPTION OF THE INVENTION

The present invention provides a method of fabricating substrate for package of semiconductor light-emitting device.

A substrate for a package of at least one semiconductor device, in accordance with the invention comprises a base, N bonding parts, N outer electrodes, and an insulating material. It should be noted that N is a positive integer larger than or equal to 2. In practice, the at least one semiconductor device is a semiconductor light-emitting device.

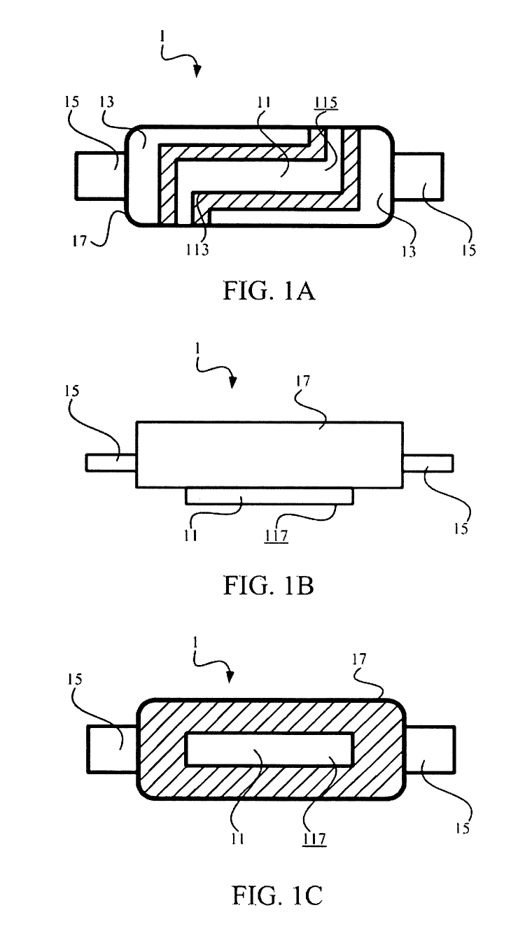

Please refer to FIG. 1A, FIG. 1B, and FIG. 1C which shows respectively a top view, a side view, and a bottom view of a substrate 1 for a package of at least one semiconductor device (not shown) according to one embodiment of the invention. In the embodiment, the substrate 1 comprises a base 11, two bonding parts 13, two outer electrodes 15, and an insulating material 17.

The base 11 has a circumference 113, a bottom surface 117 and a top surface 115. Moreover, the at least one semiconductor device is to be mounted on the top surface 115 of the base 11. In practice, the base 11 can be formed of a thick-walled metal material.

The bonding parts 13, which each has a respective bond pad (not shown), are disposed around the circumference 113 of the base 11, and spaced from the base 11. In addition, at least one of the electrodes of the at least one semiconductor device is to be wired to the bond pads of the bonding parts 13. Moreover, the outer electrodes 15 each protrudes from one of the bonding parts 13. In practice, the boding parts 13 and the outer electrodes 15 are monolithically formed of a thin-walled metal material.

Additionally, the insulating material 17 is molded to substantially pack the base 11, and the bonding parts 13, so as to expose the top surface 115 and the bottom surface 117 of the base 11, and the bond pads. Furthermore, the insulating material 17 can also be molded to form a barricade surrounding the bond pads and the top surface 115 of the base 11. In practice, the insulating material 17 can be a polymer material or a ceramic material.

After the package of the at least one semiconductor device is finished, a heat generated during operation of the at least one semiconductor device is conducted from the top surface 115 to the bottom surface 117 of the base 11, and then it is dissipated from the bottom surface 117 of the base 11.

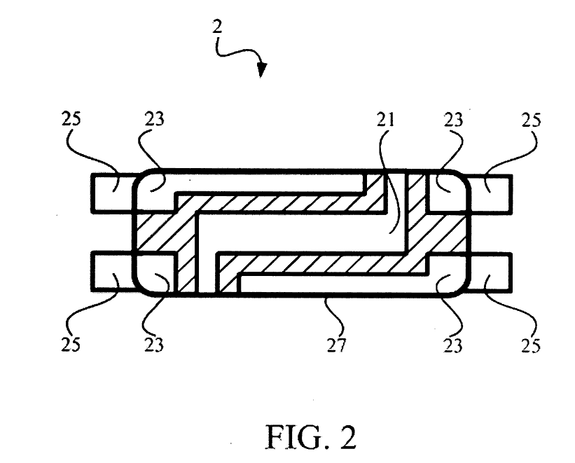

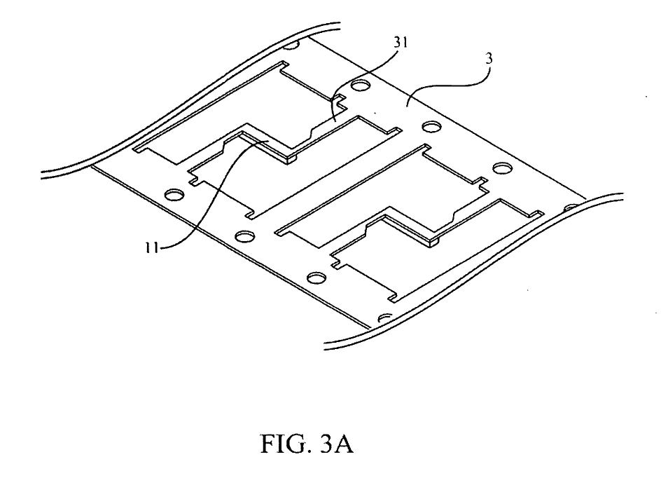

In another embodiment, as shown in FIG. 2, the substrate 2 for a package of a package of at least one semiconductor device (not shown) comprises a base 21, four bonding parts 23, four outer electrodes 25, and an insulating material 27.

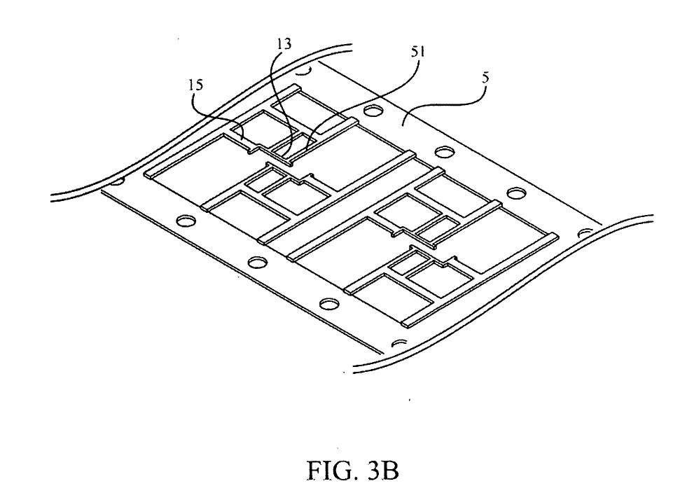

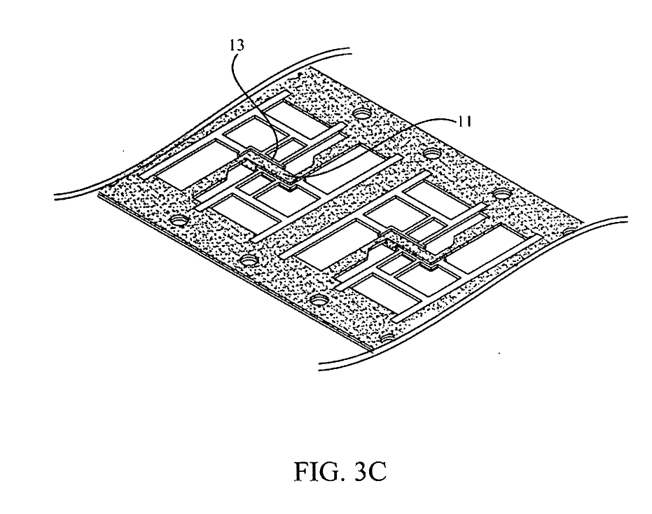

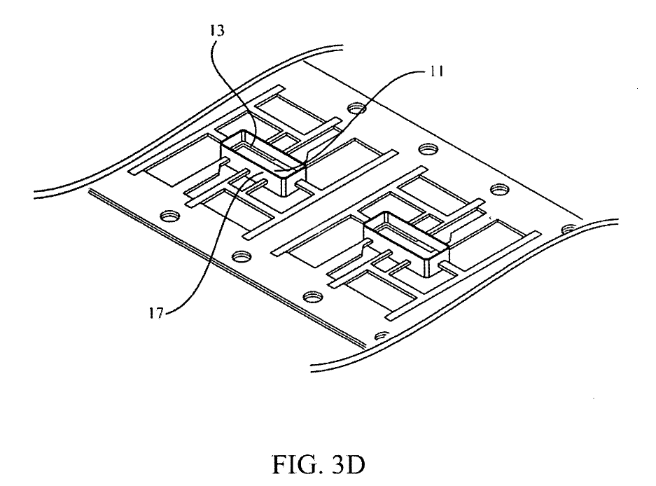

Please refer to FIG. 3A through 3D, which show a method of fabricating a substrate for a package of at least one semiconductor device according to one embodiment of the invention. The method of fabricating a substrate for a package of at least one semiconductor device, e.g. a semiconductor light-emitting device, in accordance with the present invention comprises 4 main steps.

First, as shown in FIG. 3A, a first metal plate is punched to form a first frame 3. Thus, a base 11 which has a bottom surface and a top surface is substantially formed at a center of the first frame 3. Furthermore, at least one first supporting part 31 is also formed, and each of them is to connect between the first frame 3 and the base 11. In practice, the first metal plate is a special-shaped metal plate or a normal-shaped metal plate. Moreover, in practice, the first metal plate can be a steel plate, a copper plate or an aluminum plate.

Afterward, referring to FIG. 3B, a second metal plate is punched to form a second frame 5 which can mate with the first frame 3. On the second frame 5, N bonding parts 13, which each has a respective bond pad, are formed apart from a center of the second frame 5. Moreover, N outer electrodes 15, which each is formed to connect between the second frame 5 and one of the bonding parts 13, are formed. Although N is equal to 2 in the embodiment, it should be noted that N is a positive integer larger than or equal to 2. In practice, the thickness of the second metal plate is smaller than or equal to that of the first metal plate.

In one embodiment, as shown in FIG. 3B, the second metal plate 5 is also punched to form at least one second supporting part 51 which each is formed to connect between the second frame 5 and one of the bonding parts 13. Furthermore, after the package of the at least one semiconductor device is finished, the at least one second supporting part 51 is also removed.

Referring to FIG. 3C, the third step is about aligning the second frame with the first frame, such that the bonding parts 13 are disposed around the circumference of the base 11 and spaced from the base 11.

The last step, as shown in FIG. 3D, is to mold an insulating material 17, e.g. a polymer material or a ceramic material, to substantially pack the base 11 and the bonding parts 13, so as to expose the top surface and the bottom surface of the base 11 and the bond pads. When the at least one semiconductor device is to be mounted on the top surface of the base 11, the electrodes of the at least one semiconductor device are to be wired to the first bond pads.

In one embodiment, the insulating material is also molded to form a barricade surrounding the bond pads and the top surface. Furthermore, a transparent polymer material can then be filled into the barricade to seal the at least one semiconductor device, the base, and the bond pads during the package of the at least one semiconductor device.

In one embodiment, the method of fabricating a substrate for a package of at least one semiconductor device can further comprise the step of selectively removing the first frame together with the at least one first supporting part and/or the second frame.

In one embodiment, after the package of the at least one semiconductor device is finished, a heat generated during operation of the at least one semiconductor device is conducted from the top surface to the bottom surface of the base, and then it is dissipated at the bottom surface of the base.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of fabricating a substrate for a package of at least one semiconductor device, said method comprising the steps of:
(a) punching a first metal plate to form a first frame, a base substantially formed at a center of the first frame, and at least one first supporting part which each is formed to connect between the first frame and the base, wherein the base has a circumference, a bottom surface and a top surface;
(b) punching a second metal plate to form a second frame mating the first frame, N bonding parts formed apart from a center of the second frame, and N outer electrodes which each is formed to connect between the second frame and one of the bonding parts, N being a positive integer larger than or equal to 2, wherein each of the bonding parts has a respective bond pad;
(c) aligning the second frame with the first frame, and palletizing the second frame on the first frame such that the bonding parts are disposed around the circumference of the base and spaced from the base; and
(d) molding an insulating material to substantially pack the base and the bonding parts so as to expose the top surface and the bottom surface of the base and the bond pads;
wherein the at least one semiconductor device is to be mounted on the top surface of the base, the electrodes of the at least one semiconductor device are to be wired to the bond pads.

2. The method of claim 1, further comprising the step of:
(e) selectively removing the first frame together with the at least one first supporting part and/or the second frame.

3. The method of claim 2, wherein after the package of the at least one semiconductor device is finished, a heat generated during operation of the at least one semiconductor device is conducted from the top surface to the bottom surface of the base, and then is dissipated at the bottom surface of the base.

4. The method of claim 3, wherein the first metal plate is a special-shaped metal plate or a normal-shaped metal plate.

5. The method of claim 3, wherein the thickness of the first metal plate is larger than or equal to that of the second metal plate.

6. The method of claim 3, wherein each of the at lest one semiconductor device is a semiconductor light-emitting device.

7. The method of claim 3, wherein the insulating material is a polymer material or a ceramic material.

8. The method of claim 3, wherein in step (d), the insulating material is also molded to form a barricade surrounding the bond pads and the top surface of the base, and a transparent polymer material is filled into the barricade to seal the at least one semiconductor device, the base and the bond pads during the package of the at least one semiconductor device.

9. The method of claim 3, wherein in step (b), the second metal plate is also punched to form at least one second supporting part which each is formed to connect between the second frame and one of the bonding parts, after the package of the at least one semiconductor device is finished, the at least one second supporting part is also removed.

10. A substrate for a package of at least one semiconductor device, said substrate comprising:
a base having a circumference, a bottom surface and a top surface which the at least one semiconductor device is to be mounted on;
N bonding parts which each is disposed around the circumference of the base, are spaced from the base, and has a respective bond pad which at least one of the electrodes of the at least one semiconductor device is to be wired to, N being a positive integer larger than or equal to 2;
N outer electrodes which each protrudes from one of the bonding parts;
an insulating material molded to substantially pack the base, the bonding parts so as to expose the top surface and the bottom surface of the base, and the bond pads;
wherein after the package of the at least one semiconductor device is finished, a heat generated during operation of the at least one semiconductor device is conducted from the top surface to the bottom surface of the base, and then is dissipated at the bottom surface of the base.

11. The substrate of claim 10, wherein the base is formed of a thick-walled metal material, and the boding parts and the outer electrodes are monolithically formed of a thin-walled metal material.

12. The substrate of claim 11, wherein the insulating material is also molded to form a barricade surrounding the bond pads and the top surface of the base.

13. The substrate of claim 11, wherein each of the at lest one semiconductor device is a semiconductor light-emitting device.

14. The substrate of claim 11, wherein the insulating material is a polymer material or a ceramic material.
